(19) United States
(12) Patent Application Publication
(10) Pub. No.: US 2008/0048137 A1
(43) Pub. Date: Feb. 28, 2008

(54) FRONT FILTER AND PLASMA DISPLAY PANEL AND RELATED TECHNOLOGIES

(75) Inventors: Hyun Chul Kim, Seoul (KR); Myung Won Lee, Seoul (KR); Jin San Moon, Suwon-si (KR); Jung Chul Shin, Seoul (KR)

Correspondence Address: FISH & RICHARDSON P.C., P.O. BOX 1022, MINNEAPOLIS, MN, 55440-1022, US

(73) Assignee: LG ELECTRONICS INC., Seoul (KR)

(21) Appl. No.: 11/829,584

(22) Filed: Jul. 27, 2007

(30) Foreign Application Priority Data
Jul. 27, 2006 (KR) 10-2006-0070641

(51) Int. Cl. H05K 9/00; B29D 11/00

(52) U.S. Cl. 250/515.1; 264/1.7

(57) ABSTRACT

A front filter for display panels may include a resin layer including depressed portions formed thereon and an electromagnetic wave shielding film having a conductive material injected into the depressed portions.

### CROSS-REFERENCE TO RELATED APPLICATION

This application claims the benefit of Korean Patent Application No. 10-2006-0070641, filed on Jul. 27, 2006, which is hereby incorporated by reference in its entirety as if fully set forth herein.

### BACKGROUND

1. Field

The present disclosure relates to a front filter for a display device.

2. Discussion of the Related Art

Some display devices have high definition and large size, and can display colors near natural colors. For instance, liquid crystal displays (LCD), plasma display panels (PDP), and projection televisions have been developed to display high-definition images However, filterable electromagnetic waves, which may be harmful to humans, are generated from a PDP during operation of the PDP.

### SUMMARY

[F&R to add after claims finalized].

The details of one or more implementations are set forth in the accompanying drawings and the description below. Other features will be apparent from the description and drawings.

### BRIEF DESCRIPTION OF THE DRAWINGS

FIGS. 1 to 4 are views illustrating an example of a method of manufacturing a front filter.

FIG. 5 is a view of an example of a front filter.

FIGS. 6 to 10 are views illustrating an example of a method of manufacturing a plasma display panel.

FIG. 11 is a view illustrating an example of a plasma display panel.

### DETAILED DESCRIPTION

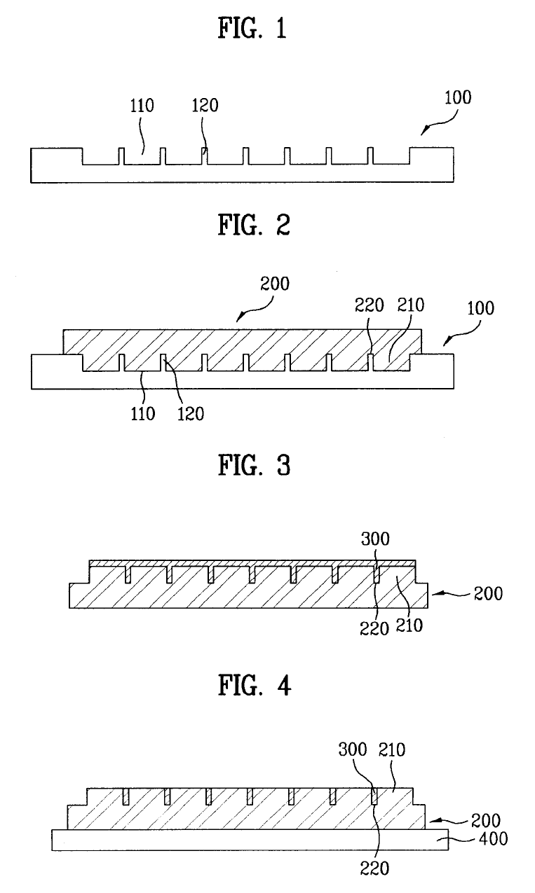

FIGS. 1 to 4 illustrate an example of a method of manufacturing a front filter.

As shown in FIG. 1, a mold 100 having depressed portions 110 (e.g., depressed carvings, indentations, recessed channels, cavities, etc.) formed in the mold may be prepared. The mold 100 may be used to form an electromagnetic wave shielding film pattern on a resin layer, which will be described in more detail below. In some examples, the depressed portions 110 may be formed in a shape configured to produce a shape of the electromagnetic wave shielding film through application of the mold. In these examples, the depressed portions 110 formed in the mold 100 may be transferred to a resin layer in the shape of embossed portions (e.g., raised portions, protrusions, projections, etc.), and the steps 120 (e.g., raised portions of the mold) between the respective depressed portions 110 may be transferred to the resin layer in the shape of depressed portions.

The steps 120 may be provided in the mold 100 in a stripe type structure or pattern or a mesh type structure or pattern depending upon the desired shape of the electromagnetic wave shielding film. In some implementations, lines included in the electromagnetic wave shielding film may be formed as a pattern in the shape of a rectangle, trapezoid, or circle. In these implementations, the depressed portions 110 included in the mold 100 may be in a shape corresponding to the electromagnetic wave shielding film. For example, the depressed portions 110 included in the mold may be in the shape of a rectangle or they may instead be in a shape different from a rectangle.

As shown in FIG. 2, depressed portions may be formed in a resin layer 200 using the mold 100. For example, the resin layer 200 may be applied to the mold 100 and then dried. In this example, because the mold 100 has the electromagnetic wave shielding film pattern formed therein, depressed portions may be formed in the resin layer 200 in the shape of the electromagnetic wave shielding film pattern. The resin layer 200 may be made of, for example, polydimethylsiloxane (PDMS), polymethylmethacrylate (PMMA), or ethylene vinyl acetate (EVA). In some implementations, the resin layer 200 is transparent because the resin layer 200 is part of a front filter used to cover a front surface of a display device (e.g., a PDP). In these implementations, the front filter does not materially impact viewing of a display image produced by the display device because the resin layer 200 is transparent. The resin layer 200 having the above-described composition may serve to protect a display device (e.g., a PDP) from external impacts after the front filter is produced and attached to the display device (e.g., a PDP). In implementations in which the shape of the electromagnetic wave shielding film pattern is formed in the resin layer 200 using the mold 100, the resin layer 200 may have viscoelastic properties.

In implementations in which the resin layer 200 is applied to the mold and is then dried as described above, depressed portions 220 (e.g., depressed carvings, indentations, recessed channels, cavities, etc.) may be formed on the resin layer 200. In these implementations, pressure may be applied to press the resin layer 200 against the mold 100 such that the formation of the depressed portions 220 in the resin layer 200 may be more easily accomplished.

The resin layer 200 may have a thickness of 30 to 700 microns. In implementations in which the thickness of the resin layer 200 is, for instance, greater than 30 microns, the resin layer 200 may effectively protect a display device (e.g., PDP). In implementations in which the thickness of the resin layer 200 is, for instance, less than 700 microns, the weight of the resin layer 200 may be desirably light. The resin layer 200 may be transparent regardless of its thickness.

In implementations in which the resin layer 200 is dried subsequent to being applied to the mold 100, the drying temperature may be 50 to 300° C. In some implementations, the drying temperature may be 100 to 200° C. The drying temperature may differ based on the material of the resin layer 200 and may include a greatly different temperature range for materials other than PDMS, PMMA, and EVA.

In some implementations, the mold 100 may be separated from the resin layer 200 after the drying process is completed. In these implementations, the depressed portions 220 may be formed in the resin layer 200. For example, the depressed portions 110 of the mold 110 may be transferred to the resin layer 200 as steps 210, and the steps 120 of the mold 110 may be transferred to the resin layer 200 as depressed portions 220. The depressed portions 220 of the resin layer 200 may have a depth of 20 to 200 microns. In some implementations, the depth of the depressed portions 220 is sufficient to receive an injection of a conductive material for shielding electromagnetic waves and ink (e.g., black ink) for improving contrast. The depressed portions 220 formed in the resin layer 200 may be formed in either a stripe type structure or pattern or a mesh type structure or pattern.

As shown in FIG. 3, a conductive material 300 may be injected into the depressed portions 220 formed in the resin layer 200. The conductive material may form an electromagnetic wave shielding film. For example, a conductive material, including at least one of silver (Ag) paste, copper (Cu) paste, ink including a complex salt of silver nitrate (AgNO₃), or ink including a complex salt of silver (Ag), may be injected into the depressed portions 220 formed in the resin layer 200. In some examples, the amount of the conductive material 300 may be greater than the receiving spaces of the depressed portions 220. In these examples, a portion of the conductive material 300 may be discharged to the top of the resin layer 200. When the portion of the conductive material 300 is discharged to the top of the resin layer 200, a leveling process may be performed using a metal or plastic blade to level the surface of the resin layer 200.

In implementations in which the electromagnetic wave shielding film is formed using only a conductive material, picture quality may be negatively impacted (e.g., sparkling or flickering may occur) due to reflection of light by the conductive material. In these implementations, black ink may be used to improve the contrast. For example, black ink (not shown) may be further injected onto the conductive material 300 in the depressed portions 220 of the resin layer 200. The amount of the conductive material 300 may be adjusted to compensate for the black ink. In some examples, a blade may be used to prevent the black ink from being discharged to the top of the resin layer 200. In some implementations, the black ink has a thickness equivalent to 10 to 50% of the thickness of the electromagnetic wave shielding film. The improvement of contrast may be significant or at least sufficient if the amount of black ink used is sufficiently large. On the other hand, brightness may be enhanced or maintained at a sufficient level if the amount of black ink used is sufficiently low.

An electromagnetic wave shielding film (e.g., as formed through the above-described process) may be constructed in a one-layered structure including only the conductive material or in a two-layered structure including the conductive material and the black ink. In some implementations, the respective lines forming the stripe or mesh type electromagnetic wave shielding film may have a diameter of 10 to 30 microns. Restricting the diameter of the respective lines may maintain the aperture ratio of the display device. In implementations in which the aperture ratio of the display device is maintained, the respective lines may be spaced apart from each other by 150 to 500 microns. In some implementations, the lines may be spaced apart approximately 300 microns.

As shown in FIG. 4, the resin layer 200, having the electromagnetic wave shielding film formed thereon, may be joined to a glass or film 400 to complete a front filter. In implementations in which the resin layer 200 is joined to the glass, a glass type front filter is obtained. In implementations in which the resin layer 200 is joined to film (e.g., a polyethylene terephthalate (PET) film), a film type front filter is obtained. The resin layer 200 may be formed on the glass or film 400 using an adhesive layer (not shown), such as a pressure sensitive adhesive (PSA). In some implementations, the resin layer 200, having the electromagnetic wave shielding film formed thereon, may be directly joined to a display panel.

In some implementations, a near infrared ray shielding film, a color correction film, and/or a reflection preventing film may be formed on the resin layer 200 in addition to the electromagnetic wave shielding film. In these implementations, the performance of the front filter may be improved. In some examples, dyes for color correction and near infrared ray shielding may be included in the resin layer 200 or the adhesive layer, such as PSA, to reduce the thickness and weight of the front filter.

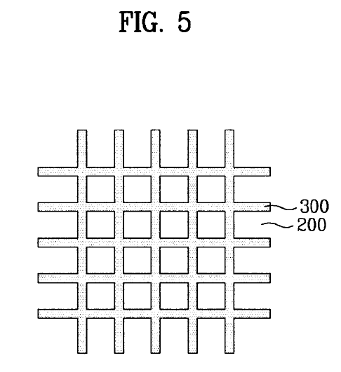

FIG. 5 illustrates a plan view of an example of a front filter. Referring to FIG. 5, the electromagnetic wave shielding film is formed in a structure in which the conductive material 300 is disposed on the resin layer 200 in a mesh shape. In implementations in which black ink is disposed on the resin layer 200, the black ink, instead of the conductive material 300, is shown in the plan view.

The front filter of a plasma display panel may be directly formed on front glass of the plasma display panel. In some implementations, the lattice interval and lattice pattern of the electromagnetic wave shielding film of the front filter may be uniformly maintained. In some implementations, a resin layer, having a high viscoelasticity, is disposed at a front of the glass or film. In these implementations, the thickness and weight of the front filter may be reduced and the display device (e.g., the PDP) may be protected from external impacts.

Viscoelasticity is a phenomenon in which, when a force is applied to an object, elastic deformation and viscosity simultaneously occur. That is, viscoelasticity exhibits both liquid characteristics and solid characteristics. In implementations in which a resin layer having viscoelasticity is used, the resin layer may have an impact strength 1.5 to 2 times greater than that of resin layers that do not have viscoelastic properties. In these implementations, the conductive material may be deeply inserted into the depth of the depressed portions formed in the resin layer because low resistance is accomplished. In these implementations, the electromagnetic wave shielding effect may be maximized.

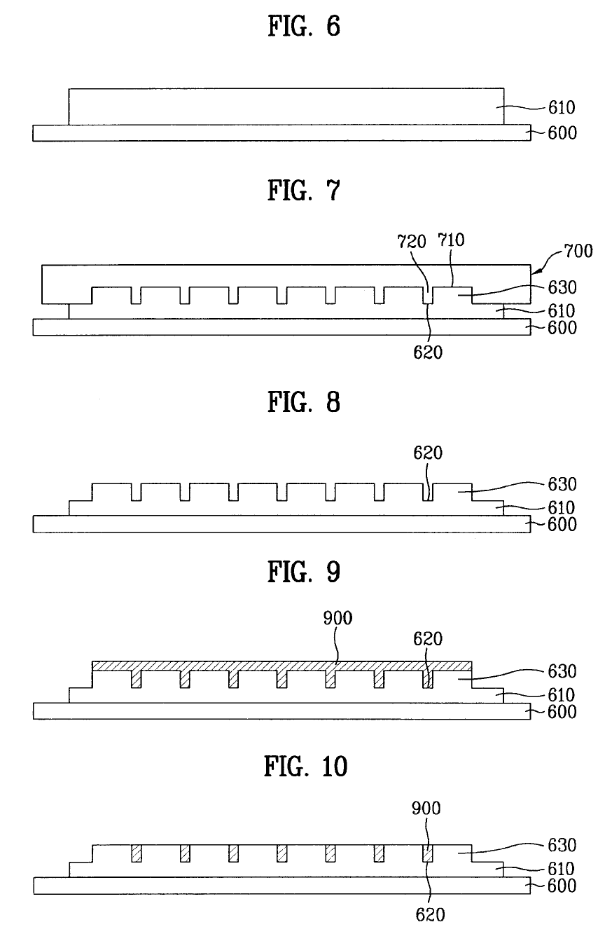

FIGS. 6 to 10 illustrate an example of a method of manufacturing a plasma display panel.

As shown in FIG. 6, a resin layer 610 may be formed on a front glass 600 of the plasma display panel. The front glass 600 may be disposed on a front panel or surface of the plasma display panel. A glass substrate for display panels may be used as the front glass 600. As discussed above with respect to the resin layer 200, the resin layer 610 may be made of PDMS, PMMA, or EVA. In some implementations, the resin layer 610 is transparent because the resin layer 610 is part of the front filter. In some examples, the resin layer 610 may be directly joined to the front glass 600. In other examples, the resin layer 610 may be joined to the front glass 600 using an adhesive layer, such as PSA. The resin layer 610 may have a thickness of 30 to 700 microns.

As shown in FIG. 7, depressed portions 620 may be formed in the resin layer 610 using a mold 700. The mold 700 may be used to form an electromagnetic wave shielding film pattern on the resin layer 610, which will be described in more detail below. The depressed portions 620 may be formed in a shape inverted to the shape of the electromagnetic wave shielding film. In some implementations, the depressed portions 620 and steps 720 are alternately positioned as the mold 700 is pressed to the resin layer 610. In implementations in which the mold 700 is pressed onto the resin layer 610, the pattern of the mold 700 is transferred to the resin layer 610 in an inverted shape, whereby the electromagnetic wave shielding film pattern is formed in the resin layer 610. For example, the depressed portions 710 of the mold 700 may be transferred to the resin layer 610 in the shape of steps 630, and the steps 720 of the mold 700 may be transferred to the resin layer 610 in the shape of depressed portions 620.

In implementations in which the mold 700 is separated from the resin layer 610, the electromagnetic wave shielding film pattern may be formed in the resin layer 610, as shown in FIG. 8. The electromagnetic wave shielding film pattern may be formed in a stripe type structure or pattern or a mesh type structure or pattern. For example, the electromagnetic wave shielding film pattern may be obtained by forming the depressed portions 620 and the steps 630 at the resin layer 610. In some implementations, the depressed portions 620 of the resin layer 610 have a depth of 20 to

200 microns from the top of the corresponding steps 630.

As shown in FIG. 9, a conductive material 900 may be injected into the electromagnetic wave shielding film pattern formed in the resin layer 610. For example, a conductive material, including at least one of silver (Ag) paste, copper (Cu) paste, ink including a complex salt of silver nitrate (AgNO₃), and ink including a complex salt of silver (Ag), may be injected into the depressed portions 620 formed in the resin layer 610. Similar to the method of manufacturing the front filter described above with respect to FIGS. 1 to 4, a leveling process may be performed using a metal or plastic blade to level the surface of the resin layer 610. In some implementations, black ink (not shown) may be further injected onto the conductive material 900 to improve the contrast, as previously described. The conductive material and the black ink may be injected using an inkjet method. In some implementations, the black ink has a thickness equivalent to 10 to 50% of the total thickness of the electromagnetic wave shielding film.

An electromagnetic wave shielding film (e.g., as formed through the above-described process), may be constructed in a one-layered structure including only the conductive material or in a two-layered structure including the conductive material and the black ink. In some implementations, the respective lines forming the stripe or mesh type electromagnetic wave shielding film may have a diameter of 10 to 30 microns. In some examples, the respective lines may be spaced apart from each other by 150 to 500 microns so as to maintain the aperture ratio of the PDP. The electromagnetic wave shielding film may be constructed in a single-layered structure including a mixture of the conductive material and the black material (ink).

In the process described with reference to FIGS. 6-9, a front filter of the PDP configured to perform an electromagnetic wave shielding function may be completed. In this example, the completed front filter may not be a glass type front filter nor a film type front filter. The front filter may be directly formed at the front glass of the PDP. The remaining PDP manufacturing processes excluding the front filter forming process may be unchanged.

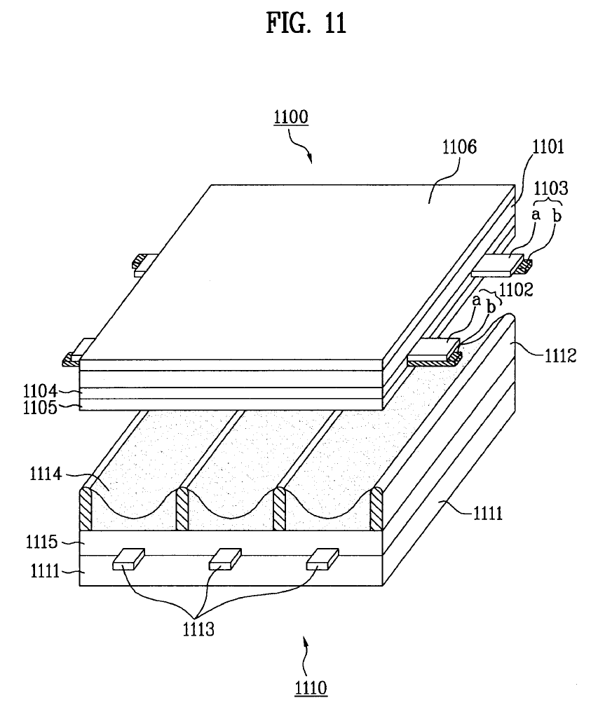

FIG. 11 illustrates an example of the structure of a plasma display panel.

A plasma display panel may be manufactured through a glass forming process, a front substrate manufacturing process, a rear substrate manufacturing process, an assembling process, or a front filter manufacturing process.

The front substrate manufacturing process includes several processes. For example, the front substrate manufacturing process may include a process for forming a scan electrode and a sustain electrode on a front glass and a process for forming an upper dielectric layer. The upper dielectric layer may restrict the discharge current of the scan electrode and the sustain electrode and insulate the electrode pair from each other. The front substrate manufacturing process also may include a process for forming a passivation film, having magnesium oxide deposited thereon. The film may be configured to accomplish discharge on the upper dielectric layer.

The rear substrate manufacturing process includes several processes. For example, the rear substrate manufacturing process may include a process for forming address electrodes on a rear glass, a process for forming a lower dielectric layer for protecting the address electrodes, a process for forming partition walls for partitioning discharge cells on the top of the lower dielectric layer, and a process for forming a fluorescent substance layer to emit visible rays for picture display between the partition walls.

The plasma display panel manufactured through the above-described processes may be constructed in a structure in which a sustain electrode pair, including a scan electrode 1102 and a sustain electrode 1103, is arranged on the picture display surface of a front panel 1100, e.g., a front glass 1101, as shown in FIG. 11. A plurality of address electrodes 1113 may be arranged on a rear glass 1111 of a rear panel 1110 such that the address electrodes 1113 intersect the sustain electrode pair. The rear panel 1110 and the front panel 1100 may be coupled to each other in parallel and may be spaced a predetermined distance from each other.

Stripe (or well) type partition walls 1112 for forming a plurality of discharge spaces, e.g., discharge cells, may be arranged on the rear panel 1100. The partition walls 1112 may be in parallel with each other. The address electrodes 1113, which may perform address discharge to generate vacuum ultraviolet rays, may be arranged in parallel with the partition walls 1112. A red, green, blue (RGB) fluorescent substance 1114 configured to emit visible rays for picture display during the address discharge may be applied to the top of the rear panel 1110. Between the address electrodes 1113 and the fluorescent substance 1114 may be formed a lower dielectric layer 1115 configured to protect the address electrodes 1113.

On the front glass 1101, a front filter 1106 may be formed. As previously described, the front filter 1106 may be manufactured by patterning a conductive material and black ink on a resin layer to form an electromagnetic wave shielding film. As also previously described, a near infrared ray shielding film, a color correction film, and/or a reflection preventing film may be formed on the resin layer including the electromagnetic wave shielding film to improve the performance of the front filter. In some implementations, dyes for color correction and near infrared ray shielding may be included in the resin layer to reduce the thickness and weight of the front filter.

The front filter for plasma display panels and the method of manufacturing the front filter described above may be applicable to display devices included in other applications requiring an electromagnetic wave shielding function.

It will be understood that various modifications may be made. For example, other useful implementations could be achieved if steps of the disclosed techniques were performed in a different order and/or if components in the disclosed systems were combined in a different manner and/or replaced or supplemented by other components. Accordingly, other implementations are within the scope of the following claims.

What is claimed is:

1. A front filter comprising:
a resin layer including at least one depressed portion extending from a surface of the resin layer into the resin layer to form one or more reservoirs configured to accommodate a conductive material; and
an electromagnetic wave shielding film including the conductive material accommodated by the one or more reservoirs formed by the at least one depressed portion of the resin layer.

2. The front filter according to claim 1, wherein the conductive material is contained by the one or more reservoirs formed by the at least one depressed portion of the resin layer.

3. The front filter according to claim 1, wherein the conductive material is positioned within the one or more reservoirs formed by the at least one depressed portion of the resin layer.

4. The front filter according to claim 1, wherein the conductive material fills the one or more reservoirs formed by the at least one depressed portion of the resin layer and a portion of the conductive material extends outside of the one or more reservoirs.

5. The front filter according to claim 1, further comprising:
a glass, a film, or a display panel, the resin layer being coupled to the glass, the film, or the display panel.

6. The front filter according to claim 1, further comprising:
ink provided on the conductive material.

7. The front filter according to claim 1, wherein the resin layer is made of at least one of polydimethylsiloxane (PDMS), polymethylmethacrylate (PMMA), or ethylene vinyl acetate (EVA).

8. The front filter according to claim 1, wherein the resin layer has a thickness of 30 to 700 microns.

9. The front filter according to claim 8, wherein the at least one depressed portion has a depth of 20 to 200 microns.

10. The front filter according to claim 1, wherein the conductive material includes at least one of silver (Ag) paste, copper (Cu) paste, ink including a complex salt of silver nitrate (AgNO₃), or ink including a complex salt of silver (Ag).

11. A method of manufacturing a front filter, comprising:
obtaining a resin layer;
producing at least one depressed portion extending from a surface of the resin layer into the resin layer to form one or more reservoirs configured to accommodate a conductive material;
introducing the conductive material into the one or more reservoirs formed by the at least one depressed portion; and
coupling the resin layer to a glass, a film, or a display panel such that the conductive material is positioned and oriented relative to the glass, the film, or the display panel in a fixed manner.

12. The method according to claim 11, wherein producing at least one depressed portion extending from the surface of the resin layer into the resin layer to form one or more reservoirs configured to accommodate the conductive material comprises forming at least one depressed portion extending from the surface of the resin layer into the resin layer to form one or more reservoirs configured to accommodate the conductive material.

13. The method according to claim 11, wherein introducing the conductive material into the one or more reservoirs formed by the at least one depressed portion comprises injecting the conductive material into the one or more reservoirs formed by the at least one depressed portion.

14. The method according to claim 11, further comprising:
leveling, using a blade, the conductive material injected into the one or more reservoirs formed by the at least one depressed portion.

15. The method according to claim 11, further comprising:
injecting ink into the one or more reservoirs formed by the at least one depressed portion.

16. The method according to claim 15, further comprising:
leveling, using a blade, the ink.

17. The method according to claim 11, wherein forming the at least one depressed portion includes:
preparing a mold having at least one raised portion, the at least one raised portion being configured in a shape of an electromagnetic wave shielding film pattern;
applying the resin layer to the mold such that the at least one raised portion contacts the surface of the resin layer;
pressing the resin layer against the mold;
drying the resin layer; and
separating the mold from the resin layer such that the resin layer includes at least one depressed portion corresponding to the at least one raised portion of the mold, the at least one depressed portion being configured in the shape of the electromagnetic wave shielding film pattern.

18. The method according to claim 17, wherein drying the resin layer includes drying the resin layer at a temperature of 50 to 300° C.

19. A plasma display panel comprising:
a front panel;
a rear panel opposing the front panel;
partition walls positioned between the front panel and the rear panel;
a front filter formed on the front panel, the front filter including:
a resin layer including at least one depressed portion extending from a surface of the resin layer into the resin layer to form one or more reservoirs configured to accommodate a conductive material; and
an electromagnetic wave shielding film including the conductive material accommodated by the one or more reservoirs formed by the at least one depressed portion of the resin layer.

20. The plasma display panel according to claim 19, further comprising:
ink provided on the conductive material.

21. The plasma display panel according to claim 19, wherein the resin layer is made of at least one of PDMS, PMMA, or EVA.

22. The plasma display panel according to claim 19, wherein the resin layer has a thickness of 30 to 700 microns.

23. The plasma display panel according to claim 19, wherein the at least one depressed portion has a depth of 20 to 200 microns.

24. The plasma display panel according to claim 19, wherein the conductive material includes at least one of Ag paste, Cu paste, ink including a complex salt of AgNO₃, and ink including a complex salt of Ag.
